(19) United States
(12) Patent Application Publication
(10) Pub. No.: US 2002/0136069 A1
(43) Pub. Date: Sep. 26, 2002

(54) Method and device for reducing average access time of a non-volatile memory during reading

(75) Inventors: Riccardo Riva Reggiori, Milano (IT); Stefan Schippers, Verona (IT); Mauro Sali, Lodi (IT)

Correspondence Address: FLEIT, KAIN, GIBBONS,, GUTMAN & BONGINI, P.L., ONE BOCA COMMERCE CENTER, 551 NORTHWEST 77TH STREET, SUITE 111, BOCA RATON, FL, 33487, US

(73) Assignee: STMICROELECTRONICS S.r.l., Agrate Brianza (IT)

(21) Appl. No.: 10/033,358

(22) Filed: Dec. 28, 2001

(30) Foreign Application Priority Data
Dec. 28, 2000 (EP) 00830855.3

(51) Int. Cl. G11C 7/00; G06F 12/00

(52) U.S. Cl. 365/200; 711/103

(57) ABSTRACT

A method and a device are provided for reducing the average access time of a non-volatile memory during the reading phase. Reading is effected in either a page mode or a burst mode from a matrix array of memory cells to which recognition logic for recognizing access addresses to the memory is coupled. According to the method, there is provided a buffer memory that is coupled to the matrix array, and a predetermined number of memory words are stored in the buffer memory subsequent to a last-effected reading of the matrix array.

### CROSS-REFERENCE TO RELATED APPLICATIONS

This application is based upon and claims priority from prior European Patent Application No. 00830855.3, filed Dec. 28, 2000, the entire disclosure of which is herein incorporated by reference.

### BACKGROUND OF THE INVENTION 1. Field of the Invention

The present invention relates to non-volatile memories, and more specifically to a method for reducing the average access time of a non-volatile memory during the reading phase.

2. Description of Related Art

In the field of non-volatile memory devices, new modes of reading the non-volatile memory devices need to be provided in order to fill a firm market demand for improved reading performance.

Recently new reading modes have been introduced which were tested and used with other types of memory devices, such as volatile DRAMs and SRAMs.

One of these new methods is known as the page reading mode, whereby a memory is read by full pages containing a varying number of memory words.

Another known reading mode is the burst mode, whereby memory words are synchronously read from consecutive locations, according to a clock signal which is provided from outside of the memory device and can be adjusted by the user.

In either of these read modes, a time period of initial latency has to be waited before the memory can be accessed. This latency time is due to the set up phase of the memory device.

A user usually accesses a limited number of words at a time (e.g., one, two, four, eight, or sixteen words). This implies of necessity a latency time.

To better illustrate this point, two examples of reading effected in the page mode and the burst mode are reported in the following chart, for the reading of four consecutive words.

| | Tacc | Tacc | Tacc | Tacc | Tacc | |
|---|---|---|---|---|---|---|
| MODE | word 1 | word 2 | word 3 | word 4 | Average | Latency |
| Page | 100 ns | 35 ns | 35 ns | 35 ns | 51.25 ns | 65 ns |
| Burst | 100 ns | 25 ns | 25 ns | 25 ns | 43.75 ns | 75 ns |

It can be seen from the above chart that the initial latency time makes the access time Tacc worse in the page mode, from a potential 35 ns to an average access 51.25 ns.

The initial latency time likewise deteriorates the access time Tacc in the burst mode, from a potential 25 ns to an average access 43.75 ns.

A way to obviate this could be to increase the depth of a page being read in the page mode, or to increase the number of words being sequentially read in the burst mode (that is, the number of words simultaneously read in parallel).

Shown in the following chart are the average access times at increasing page depths in the page mode.

| | Tacc | Tacc | Tacc |
|---|---|---|---|
| DEPTH | First word | Steady state | Average |
| 2 words | 100 ns | 35 ns | 67.5 ns |
| 4 words | 100 ns | 35 ns | 51.25 ns |
| 8 words | 100 ns | 35 ns | 43.125 ns |
| 16 words | 100 ns | 35 ns | 39.0625 ns |

The chart here below shows the average access times at increasing burst depths, in the burst mode.

| | Tacc | Tacc | Tacc |
|---|---|---|---|
| DEPTH | First word | Steady state | Average |
| 2 words | 100 ns | 25 ns | 62.5 ns |
| 4 words | 100 ns | 25 ns | 43.75 ns |
| 8 words | 100 ns | 25 ns | 34.375 ns |
| 16 words | 100 ns | 25 ns | 29.6875 ns |

### SUMMARY OF THE INVENTION

In view of these drawbacks, it is an object of the present invention to overcome the above-mentioned drawbacks and to provide a reading mode, as well as a memory device to which such new mode can be applied, which has functional and structural features effective to shorten the average access time of a non-volatile memory by substantially suppressing the initial time of latency. In one preferred embodiment, there is provided a method whereby the reading phase is effected, in either the page or the burst mode, from a matrix array of memory cells with which a logic for recognizing access addresses to the memory is associated. There is also provided a memory device implementing such a reading method.

Another object of the present invention is to use a buffer memory to store a predetermined number of words subsequent to the last-effected reading. This allows the buffer memory to be used as an access predictor observing the sequential order of the readings.

Preferred embodiments of the present invention provides methods and devices for reducing the average access time of a non-volatile memory during the reading phase. Reading is effected in either a page mode or a burst mode from a matrix array of memory cells to which recognition logic for recognizing access addresses to the memory is coupled. There is provided a buffer memory that is coupled to the matrix array, and a predetermined number of memory words are stored in the buffer memory subsequent to a last-effected reading of the matrix array.

Other objects, features, and advantages of the present invention will become apparent from the following detailed description. It should be understood, however, that the detailed description and specific examples, while indicating preferred embodiments of the present invention, are given by way of illustration only and various modifications may naturally be performed without deviating from the present invention.

### BRIEF DESCRIPTION OF THE DRAWINGS

FIG. 1 shows a schematic view of a memory device according to a preferred embodiment of the present invention;

FIG. 2 shows a comparative graph of access time plotted against reading depth in the page mode between a conventional device and the device of one embodiment of the present invention; and

FIG. 3 shows a comparative graph of access time plotted against reading depth in the burst mode between a conventional device and the device of one embodiment of the present invention.

### DETAILED DESCRIPTION OF PREFERRED EMBODIMENTS

Preferred embodiments of the present invention will be described in detail hereinbelow with reference to the attached drawings.

Because the present invention is particularly suited to Flash EEPROM electronic devices integrated in a semiconductor, the following description is made with reference to this field of application. However, this is for convenience of illustration only, and the present invention is not exclusively limited to this field.

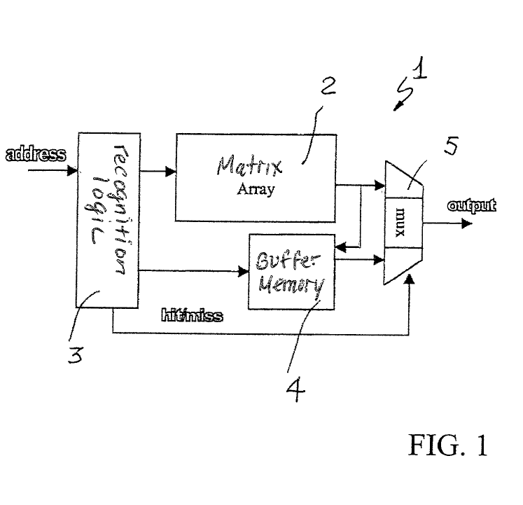

FIG. 1 shows an electronic memory device for reducing the access time of a memory during the reading phase in accordance with a preferred embodiment of the present invention.

The memory device 1 is an integrated non-volatile memory circuit, preferably but not solely of the Flash EEPROM type, and comprises a matrix array 2 of memory cells structured in rows and columns.

Associated with the matrix array 2 in a conventional manner is row and column decoding circuitry 3, which is labeled as “recognition logic” in FIG. 1. Such circuitry is supplied matrix array address signals, and is arranged to select memory locations which a user may wish to access.

Advantageously in accordance with this invention, a high-speed buffer memory 4 is associated with the memory matrix array 2, which buffer memory has inputs connected to respective outputs of the matrix array 2.

The buffer memory 4 is preferably of the volatile memory type, and more preferably of the SRAM type.

This memory 4 can contain a number n of memory words, with the number n being set by the user.

Advantageously, the number n is a function of the time lapse separating two successive accesses to the memory matrix array 2. The number n is also function of the average power consumption sought by the user in the standby condition, as explained hereinafter.

The buffer memory 4 is connected in turn to the recognition circuitry 3.

The basic structure of the device 1 according to the preferred embodiment of the present invention is completed by a multiplexer 5, which multiplexer is input the outputs from the non-volatile memory matrix array 2, the outputs from the buffer memory 4, and further outputs from the recognition logic 3.

A non-volatile memory device provided with a cache memory is disclosed in U.S. Pat. No. 5,726,937 in the name of Norand Corporation. That patent teaches the use of an SRAM as a write buffer memory wherein a microprocessor writes a data packet with high throughput. The data written in the SRAM are then written into the non-volatile memory as background.

On the other hand, the buffer memory 4 of the preferred embodiment of the present invention is expressly intended for the reading phase, and is essentially used to be ready for the next reading to the last-effected one, so as to suppress the latency time.

A method of accessing the memory according to one embodiment of the present invention will now be described.

The buffer memory 4 is used to store up one to n successive memory words relating to the last-effected reading.

Subsequent accesses to memory locations in the buffer memory 4 will have zero latency times, hereinafter referred to as “hits”.

The loading of the buffer memory 4 takes place with the memory matrix array 2 in the idle (non-selected) state, and starts from the last-read location of the matrix array 2.

The readings which allow the data to be retrieved for storing into the buffer memory 4 may be managed directly from the inside of the device 1, or may be timed by a clock provided by the user from the outside that synchronizes all the reading phases.

Advantageously in the present invention, accesses to locations of the memory matrix array 2 which do not appear in the buffer memory 4 will be burdened with no access time because a new reading phase from the memory matrix array 2 is started for them in parallel to the reading of the buffer memory 4. In this case, the buffer memory 4 would be reset and a new loading phase initiated.

The number n of words contained in the buffer memory 4 is a function of the longest jump, from the location last-accessed for reading, that the user is allowed to make with no initial latency period.

This number n may be a configurable parameter by the user, according to the performance level sought in terms of power consumption and speed.

The following chart shows average read access times against hit percentage (i.e., against accesses which produce zero latency time). The chart reflects the assumption of four memory words being read.

| | Tacc ave. | | Tacc | |
|---|---|---|---|---|
| | Standard Mem. | Tacc max | New Method | Remarks |
| 50% hits | | | | |
| Page mode | 51.25 ns | 35 ns | 43.125 ns | |
| Burst Mode | 43.75 ns | 25 ns | 34.375 ns | < burst for |
| 40 MHz | | | | eight words |
| 80% hits | | | | |
| Page Mode | 51.25 ns | 35 ns | 38.25 ns | |
| Burst Mode | 43.75 ns | 25 ns | 28.75 ns | < burst for |
| 40 MHz | | | | sixteen |

It can be seen from this chart that, for a four-word reading at 50% hits in the burst mode, the method of this embodiment of the present invention provides better average read access times than could be obtained with an eight-word deep burst mode.

Similarly for a four-word reading at 80% hits in the burst mode, the method of this embodiment of the present invention provides better average read access times than could be obtained with a sixteen-word deep burst mode.

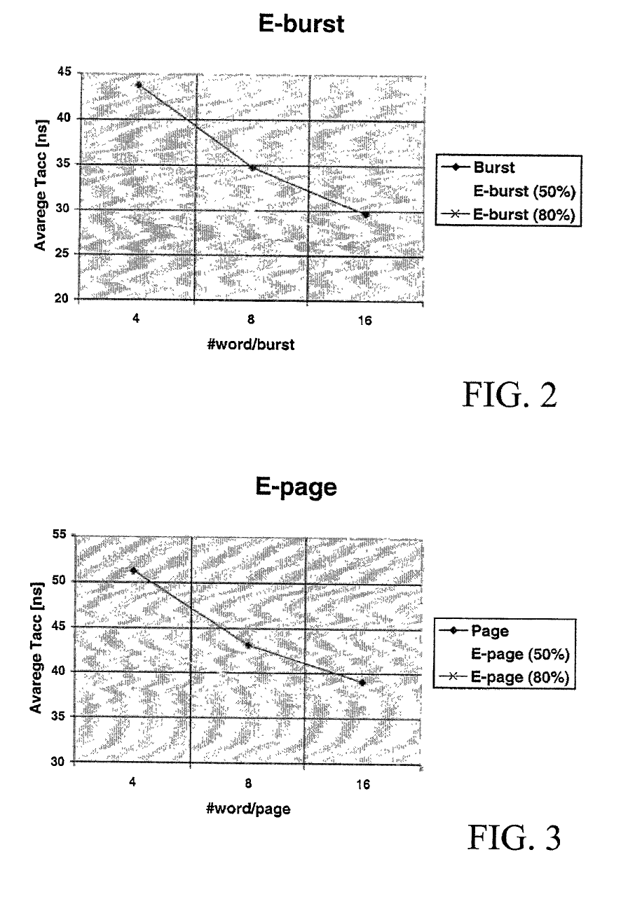

The comparative graphs of FIGS. 2 and 3 schematically illustrate the access times obtained by the method of one embodiment of the present invention and they are compared with those obtained by other reading modes on devices not incorporating a buffer memory.

It should be further noted that the buffer memory 4 is directed to read the matrix array 2 primarily by sequential accesses.

It can be appreciated from the foregoing that the method and memory device of the present invention solve the technical problem and achieve better overall results with respect to the read access time of a non-volatile memory.

While there has been illustrated and described what are presently considered to be the preferred embodiments of the present invention, it will be understood by those skilled in the art that various other modifications may be made, and equivalents may be substituted, without departing from the true scope of the present invention. Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

What is claimed is:

1. A method for reducing average time for accessing a non-volatile memory during a reading phase, with reading being effected in either a page mode or a burst mode from a matrix array of memory cells to which recognition logic for recognizing access addresses to the memory is coupled, said method comprising the steps of:
providing a buffer memory that is coupled to the matrix array; and
storing a predetermined number of memory words in the buffer memory subsequent to a last-effected reading of the matrix array.

2. The method according to claim 1, wherein the reading of the matrix array is effected with the matrix array in the idle or non-selected condition.

3. The method according to claim 1, wherein the predetermined number of memory words can be set by a user.

4. The method according to claim 1, wherein the predetermined number of memory words is a function of the average power consumption sought for a standby condition, and an average time lapse between consecutive accesses to the matrix array.

5. The method according to claim 1, wherein each new reading phase of the matrix array is effected in parallel to a reading phase of the buffer memory.

6. The method according to claim 5, wherein for those locations of the matrix array that do not appear in the buffer memory, the new reading phase is effected so as to have the buffer memory reset and re-loaded.

7. A machine-readable medium encoded with a program for reducing average time for accessing a non-volatile memory during a reading phase, with reading being effected in either a page mode or a burst mode from a matrix array of memory cells to which recognition logic for recognizing access addresses to the memory is coupled, said program containing instructions for performing the steps of:
providing a buffer memory that is coupled to the matrix array; and
storing a predetermined number of memory words in the buffer memory subsequent to a last-effected reading of the matrix array.

8. The machine-readable medium according to claim 7, wherein the reading of the matrix array is effected with the matrix array in the idle or non-selected condition.

9. The machine-readable medium according to claim 7, wherein the predetermined number of memory words can be set by a user.

10. The machine-readable medium according to claim 7, wherein the predetermined number of memory words is a function of the average power consumption sought for a standby condition, and an average time lapse between consecutive accesses to the matrix array.

11. The machine-readable medium according to claim 7, wherein each new reading phase of the matrix array is effected in parallel to a reading phase of the buffer memory.

12. The machine-readable medium according to claim 11, wherein for those locations of the matrix array that do not appear in the buffer memory, the new reading phase is effected so as to have the buffer memory reset and re-loaded.

13. An electronic memory device having reduced read access time requirements, said device comprising:
a matrix array of non-volatile memory cells readable in at least one of a page mode or a burst mode;
recognition logic for recognizing memory access addresses; and
a buffer memory coupled to the matrix array for storing up to a predetermined number of memory words subsequent to every last-effected reading of the matrix array.

14. The device according to claim 13, wherein the buffer memory is an SRAM.

15. The device according to claim 13, wherein the predetermined number of memory words contained in the buffer memory can be set by a user.

16. An information processing system that includes at least one electronic memory device having reduced read access time requirements, said memory device comprising:
a matrix array of non-volatile memory cells readable in at least one of a page mode or a burst mode;
recognition logic for recognizing memory access addresses; and
a buffer memory coupled to the matrix array for storing up to a predetermined number of memory words subsequent to every last-effected reading of the matrix array.

17. The information processing system according to claim 16, wherein the buffer memory is an SRAM.

18. The information processing system according to claim 16, wherein the predetermined number of memory words contained in the buffer memory can be set by a user.
